(19) United States
(12) Patent Application Publication
(10) Pub. No.: US 2008/0265274 A1
(43) Pub. Date: Oct. 30, 2008

(54) Light emitting diode element having a voltage regulating capability

(76) Inventor: Cheng-Sheng Yang, Nanzih District (TW)

Correspondence Address: POSZ LAW GROUP, PLC, 12040 SOUTH LAKES DRIVE, SUITE 101, RESTON, VA, 20191, US

(21) Appl. No.: 11/790,926

(22) Filed: Apr. 30, 2007

(51) Int. Cl. H01L 29/24; G05F 1/10

(52) U.S. Cl. 257/100; 315/291; 257/E29.1

(57) ABSTRACT

An LED element having a voltage regulating capability has a body, two pins, a resistor and a conductive sleeve. The resistor is connected to a shorter pin through the conductive sleeve, so an operator can easily use the conductive sleeve to cover the shorter pin and one of two terminals of the resistor. Further, to increase connecting strength among the conductive sleeve, the shorter pin and the terminal of the resistor, an operator further uses a tongs to deform the conductive sleeve to tight the pin and the terminal.

### BACKGROUND OF THE INVENTION

1. Field of the Invention

The present invention relates to a light emitting diode (LED) element, and more particularly to an LED element having a voltage regulating capability.

2. Description of Related Art

With reference to FIG. 4, a circuit diagram of a simple multi-color LED display device is shown. The display device or the like mainly has multiple light emitting diode (LED) elements (LED 1˜LED3) with different color. Further, since different color LED elements (LED1˜LED3) require different driving voltage to light, when the multi-color LED elements (LED1˜LED3) are connected in parallel and then connected to a common power source (+V), multiple resistors (R1˜R3) with different resistance are required. That is, the resistor (R1, R2 or R3) prevents the LED element (LED1, LED2 or LED3) from burning down when a large voltage inputs to the LED element. In general, one LED element (LED1, LED2 or LED3) connected to a suitable resistor (R1, R2 or R3) in serial to regulate the voltage of the LED element (LED1, LED2 or LED3).

In this example of the display device, three LED elements (LED1˜LED3), three resistors (R1˜R3) and a printed circuit board (PCB) are required. To manufacture the display device, the LED elements and the resistor are respectively soldered on the PCB.

To further increase efficiency for manufacturing the display device or the like, an improved LED element is proposed. With reference to FIG. 5, the LED element (50) has a body (51), two pins (52, 53) and a resistor (60). The two pins (52, 53) are extended from a bottom face of the body (51). One of the two pins (52, 53) is cut to shorten and then soldered to one terminal (61) of the resistor (60). A solder (70) is formed a joint of the shortened pin (52) and one terminal (141). The other terminal (62) of the resistor (60) is used as the pin of the LED element (50). Therefore, an operator only uses three improved LED elements to solder on the PCB to save assembly time.

Although the improved LED element with a resistor can save assembly time, the solder connection between the pin of the LED element (50) and the resistor (60) still has some drawbacks. For example, it is hard to solder one pin (52) of the LED element (50) and one terminal (61) of the resistor (60) since a 2.5 mm gap exists between the pin (52) and the terminal (61). As such result, a fake solder connection (70) between the pin (52) and terminal (61) causes a worse condition. That is, the pin (52) and the terminal (61) are not able to electronically connect together and the LED element (10) loses a voltage regulating capability. In addition, since a partial of the pin (141) is overlapped a partial of the pin (52), a distance between the terminal (61) of the resistor (60) and the other pin (53) is not equal to that of the two pins (52, 53).

### SUMMARY OF THE INVENTION

The main objective of the present invention is to provide a light emitting diode (LED) element that has a voltage regulating capability.

The LED element has a body, two pins, a resistor and a conductive sleeve. The resistor is connected to a shorter pin through the conductive sleeve, so an operator easily uses the conductive sleeve to cover the shorter pin and one of two terminals of the resistor. Further, to increase connecting strength among the conductive sleeve, the shorter pin and the terminal of the resistor, an operator further uses a tongs to deform the conductive sleeve to tight the pin and the terminal.

Other objectives, advantages and novel features of the invention will become more apparent from the following detailed description when taken in conjunction with the accompanying drawings.

### BRIEF DESCRIPTION OF THE DRAWINGS

FIG. 1 is an exploded perspective view of an LED element in accordance with the present invention;

FIG. 2 is a perspective view of the LED element in accordance with the present invention;

FIG. 3 is a cross sectional view in partial of the LED element in accordance with the present invention;

FIG. 4 is a circuit diagram of a simple multi-color LED display device in accordance with the prior art; and

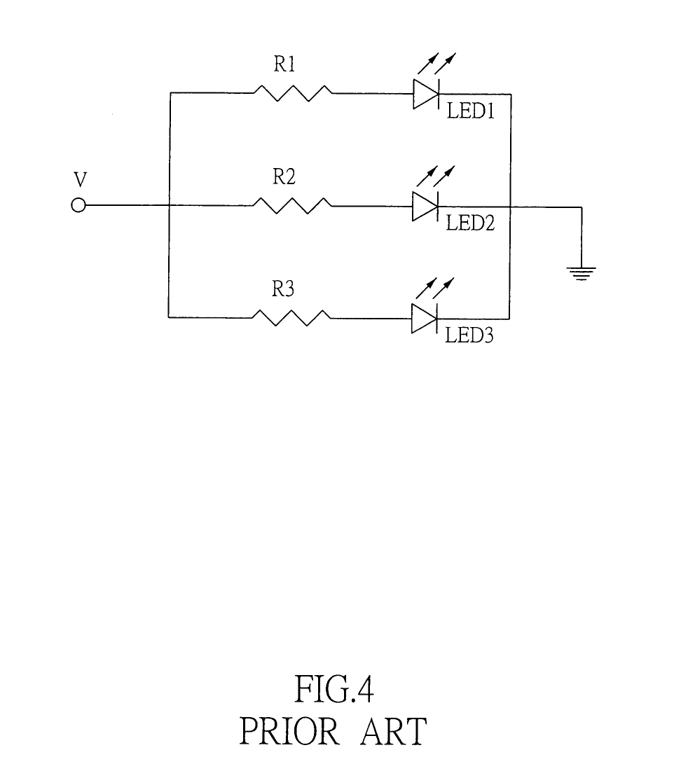

FIG. 5 is a cross sectional view in partial of a conventional LED element in accordance with the prior art.

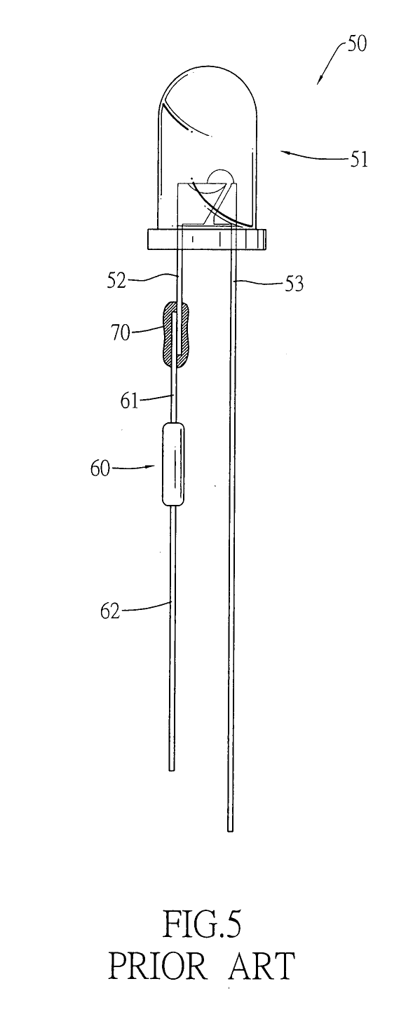

### DETAILED DESCRIPTION OF THE PREFERRED EMBODIMENT

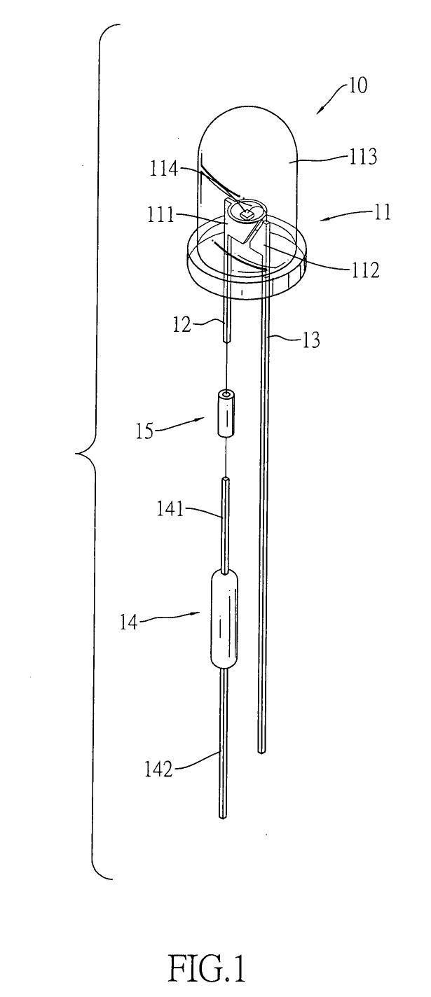

With reference to FIG. 1, a preferred embodiment of an LED element (10) has a body (11), two pins (12, 13), a resistor (14) and a conductive sleeve (15).

The body (11) has an LED chip (114), a die pad (111) extended from a top of one pin (12), an electrode pad (112) extended from a top of the other pin (13) and an encapsulation (113). The LED chip (114) mounted on the die pad (111) and then wire bonded to the electrode pad (112). The encapsulation (113) seals the die pad (111) with the LED chip (114) and the electrode pad (112).

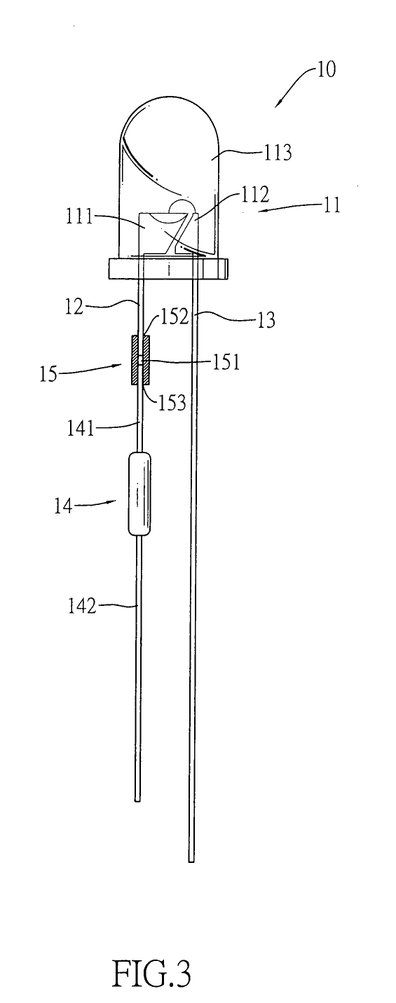

The two pins (12, 13) are extended from a bottom face of the body (11). One pin (12) is shorter than the other one (13). In this preferred embodiment, the shorter pin (12) is a pin having the extended die pad (111). With further reference to FIG. 3, the resistor (14) has two terminals (141, 142). The conductive sleeve (15) has two opposite openings (152, 153) and a through hole (151), which fits from size of the shorter pin (12) of the LED element (10) and one terminal (141) of the resistor (14). The through hole (151) communicates with the two opposite openings (152, 153).

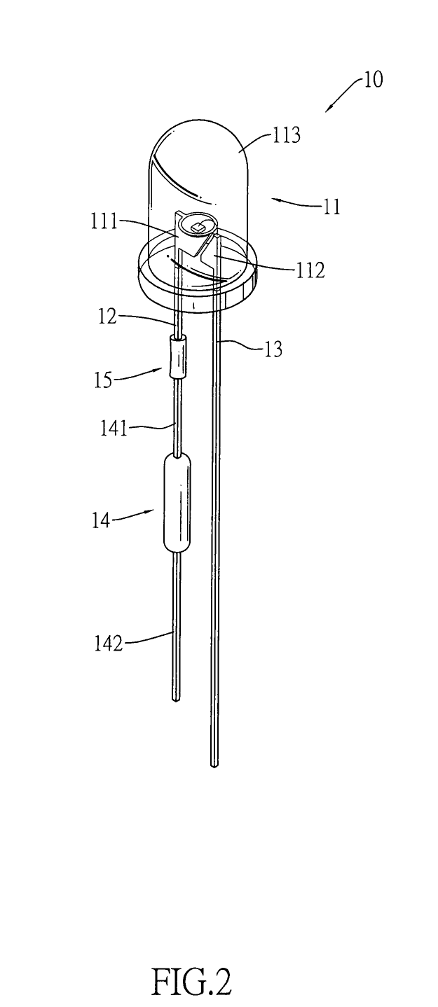

With further reference to FIGS. 2 and 3, The shorter pin (12) downwardly plugs into the through hole (151) through the upper opening (152) of the conductive sleeve (15). The terminal (141) upwardly plus into the through hole (151) through the other opening (153) of the conductive sleeve (15). As such result, the shorter pin (12) is electronically connected and aligned to the terminal (141) of the resistor (14) through the conductive sleeve (15).

In addition, to increase connecting strength among the conductive sleeve (15), the shorter pin (12) and the terminal (141), an operator can use a tongs to deform the conductive sleeve (15) to tight the shorter pin (12) and the terminal (141).

Based on the foregoing description, the LED element in accordance with the present invention uses a conductive sleeve to connect the pin and the resistor and provides better connection strength. In addition, the operator can easily connect the resistor to one of the pins of the LED element.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. An LED element having a voltage regulating capability, comprising:
a body having a bottom face;
a two pins extended from the bottom face of the body, wherein one of the two pins is shorter than the other one;
a resistor having two terminals; and
a conductive sleeve covered the shorter pin and one of the two terminals of the resistor.

2. The LED element as claimed in claim 1, the conductive sleeve comprises two opposite openings and a through hole communicating with the two opposite openings, wherein the shorter pin and one of the two terminals of the resistor are respectively inserted into through hole from the corresponding opening.

3. The LED element as claimed in claim 1, the body comprises:
an LED chip;
a die pad extended upwardly from a top of the shorter pin, wherein the LED chip is mounted on the die pad;
an electrode pad extended upwardly from a top of the other pin, wherein the LED chip is wire bond to the electrode pad; and
an encapsulation sealing the die pad with the LED chip and the electrode pad.

4. The LED element as claimed in claim 2, the body comprises:
an LED chip;
a die pad extended upwardly from a top of the shorter pin, wherein the LED chip is mounted on the die pad;
an electrode pad extended upwardly from a top of the other pin, wherein the LED chip is wire bond to the electrode pad; and
an encapsulation sealing the die pad with the LED chip and the electrode pad.
